(19) United States
(12) Patent Application Publication
(10) Pub. No.: US 2024/0251638 A1
(43) Pub. Date: Jul. 25, 2024

(54) DISPLAY DEVICE AND MANUFACTURING METHOD THEREOF

(71) Applicant: Samsung Display Co., LTD., Yongin-si (KR)

(72) Inventors: Chul Won PARK, Yongin-si (KR); So Young KOO, Yongin-si (KR); Myoung Hwa KIM, Yongin-si (KR); Geun Chul PARK, Yongin-si (KR); Joon Seok PARK, Yongin-si (KR); Hye Lim CHOI, Yongin-si (KR)

(21) Appl. No.: 18/538,365

(22) Filed: Dec. 13, 2023

(30) Foreign Application Priority Data
Jan. 19, 2023 (KR) 10-2023-0008082

(51) Int. Cl. H10K 59/80; H10K 59/12; H10K 59/122

(52) U.S. Cl. CPC H10K 59/80522; H10K 59/1201; H10K 59/122; H10K 59/873

(57) ABSTRACT

A display device includes: a substrate; a plurality of pixel electrodes that are disposed above the substrate; a first insulating layer that has a first opening and is disposed on a pixel electrode of the plurality of pixel electrodes; an auxiliary electrode that is disposed on the first insulating layer; an intermediate layer that is disposed on the pixel electrode and includes a light-emitting layer disposed within the first opening; a common electrode that is disposed on the intermediate layer; and a first encapsulating layer that is disposed above the common electrode. An end portion of the common electrode contacts a side surface of the auxiliary electrode and is electrically connected to the side surface of the auxiliary electrode, and an end portion of the first encapsulating layer is disposed at the side surface of the auxiliary electrode and is disposed lower than an upper surface of the auxiliary electrode.

This application claims priority to Korean Patent Application No. 10-2023-0008082, filed on Jan. 19, 2023, and all the benefits accruing therefrom under U.S.C. § 119, the content of which in its entirety is herein incorporated by reference.

### BACKGROUND

### (a) Field

The disclosure relates to a display device and a manufacturing method of the display device.

### (b) Description of the Related Art

A display device displays an image of image data, and a light-emitting diode display is developed as a self-emitting display device.

A plurality of pixels is disposed in a display area of the display device, and the plurality of pixels includes pixels representing basic colors such as red, green, blue, or the like.

Each pixel includes a plurality of transistors and a light-emitting element. The plurality of transistors is connected to a signal line, and may transfer a driving current to the light-emitting element. The light-emitting element may include an anode, a cathode, and a light-emitting layer disposed between the anode and the cathode, and the anode may be connected to the transistor of the pixel to receive the driving current. The light-emitting element may be implemented as a light-emitting diode, and in the light-emitting diode, a hole from the anode and an electron from the cathode meet in the light-emitting layer to emit light.

An encapsulating layer may be disposed at an upper portion of the light-emitting element of the display device to prevent a defect due to moisture permeation or the like from the outside.

### SUMMARY

Embodiments are to seal each light-emitting element of each pixel of a display device to reduce a defective rate of all pixels and prevent a leakage current between the pixels, and are to prevent moisture permeation from the outside, a lifting defect, and a defect in which an encapsulating layer is not sufficiently filled.

A display system in an embodiment of the disclosure includes: a substrate; a plurality of pixel electrodes that are disposed above the substrate; a first insulating layer in which a first opening is defined and which is disposed on a pixel electrode of the plurality of pixel electrodes; an auxiliary electrode that is disposed on the first insulating layer; an intermediate layer that is disposed on the pixel electrode and includes a light-emitting layer disposed within the first opening; a common electrode that is disposed on the intermediate layer; and a first encapsulating layer that is disposed above the common electrode. An end portion of the common electrode contacts a side surface of the auxiliary electrode and is electrically connected to the side surface of the auxiliary electrode, and an end portion of the first encapsulating layer is disposed at the side surface of the auxiliary electrode and is disposed lower than an upper surface of the auxiliary electrode.

In an embodiment, the display device may further include a second encapsulating layer disposed on the first encapsulating layer and the auxiliary electrode. The second encapsulating layer may contact an upper surface of the auxiliary electrode.

In an embodiment, the second encapsulating layer may contact a corner portion of the upper surface of the auxiliary electrode.

In an embodiment, the display device may further include a third encapsulating layer disposed on the second encapsulating layer. At least one of the first encapsulating layer and the second encapsulating layer may include an inorganic material, and the third encapsulating layer may include an organic material.

In an embodiment, the first encapsulating layer may include an inorganic material, and the second encapsulating layer may include an organic material.

In an embodiment, the auxiliary electrode may have a second opening corresponding to the first opening, and a width of the common electrode disposed within the second opening may be greater than a width of the intermediate layer disposed within the second opening.

In an embodiment, the first insulating layer may include a protrusion defining the first opening and having an undercut structure, and the display device may further include an upper pattern disposed between the protrusion and the pixel electrode.

In an embodiment, the intermediate layer may include a portion disposed below the protrusion and spaced apart from the upper pattern.

In an embodiment, the display device may further include a capping layer disposed between the common electrode and the first encapsulating layer.

In an embodiment, the auxiliary electrode may form a mesh shape at a display area where the plurality of pixel electrodes is disposed.

A display system in another embodiment of the disclosure includes: a substrate; a plurality of pixel electrodes that are disposed above the substrate; a first insulating layer in which a first opening is defined and which is disposed on a pixel electrode of the plurality of pixel electrodes; an auxiliary electrode that is disposed on the first insulating layer; an intermediate layer that is disposed on the pixel electrode and includes a light-emitting layer disposed within the first opening; a common electrode that is disposed on the intermediate layer; a first encapsulating layer that is disposed above the common electrode; and a second encapsulating layer disposed on the first encapsulating layer and the auxiliary electrode. An end portion of the common electrode contacts a side surface of the auxiliary electrode and is electrically connected to the side surface of the auxiliary electrode, and the second encapsulating layer covers the first encapsulating layer and contacts a corner portion of an upper surface of the auxiliary electrode.

In an embodiment, the second encapsulating layer may include a portion disposed on the upper surface of the auxiliary electrode and a portion disposed on the first encapsulating layer.

In an embodiment, the display device may further include a third encapsulating layer disposed on the second encapsulating layer. At least one of the first encapsulating layer and the second encapsulating layer may include an inorganic material, and the third encapsulating layer may include an organic material.

In an embodiment, the first encapsulating layer may include an inorganic material, and the second encapsulating layer may include an organic material.

In an embodiment, a second opening corresponding to the first opening may be defined in the auxiliary electrode, and a width of the common electrode disposed within the second opening may be greater than a width of the intermediate layer disposed within the second opening.

In an embodiment, the first insulating layer may include a protrusion defining the first opening and having an undercut structure, and the display device may further include an upper pattern disposed between the protrusion and the pixel electrode.

A manufacturing method of a display device in an embodiment of the disclosure includes: forming a plurality of pixel electrodes above a substrate; sequentially forming a first insulating layer and an auxiliary electrode on the plurality of pixel electrodes; stacking a first photoresist layer on the auxiliary electrode and defining a first opening overlapping a first pixel electrode of the plurality of pixel electrodes; etching the auxiliary electrode through the first opening and defining a second opening corresponding to the first opening and etching the first insulating layer and defining a third opening corresponding to the second opening; sequentially stacking a first intermediate layer material including a light-emitting material, a first common electrode material, and a first encapsulating layer material above the substrate; and removing the first photoresist layer and forming a first intermediate layer, a first common electrode, and a first encapsulating layer sequentially disposed on the first pixel electrode. An acute angle defined between a deposition direction of the first common electrode material and an upper surface of the substrate is smaller than an acute angle defined between a deposition direction of the first intermediate layer material and the upper surface of the substrate.

In an embodiment, the first photoresist layer may include a protrusion that does not overlap the auxiliary electrode around the first opening, and the first intermediate layer material incident into the first opening may be deposited to be spaced apart from the auxiliary electrode by the protrusion, and the first common electrode material may contact the auxiliary electrode by the protrusion.

In an embodiment, the manufacturing method of the display device may further include: stacking a second photoresist layer on the auxiliary electrode and defining a fourth opening overlapping a second pixel electrode of the plurality of pixel electrodes; etching the auxiliary electrode through the fourth opening and defining a fifth opening corresponding to the fourth opening and etching the first insulating layer and defining a sixth opening corresponding to the fifth opening; sequentially stacking a second intermediate layer material including a light-emitting material, a second common electrode material, and a second encapsulating layer material above the substrate; and removing the second photoresist layer and forming a second intermediate layer, a second common electrode, and a second encapsulating layer sequentially disposed on the second pixel electrode. An acute angle defined between a deposition direction of the second common electrode material and the upper surface of the substrate may be smaller than an acute angle defined between a deposition direction of the second intermediate layer material and the upper surface of the substrate.

In an embodiment, the manufacturing method of the display device may further include: stacking a first protective layer material on the first encapsulating layer material before the removing of the first photoresist layer; stacking a second protective layer material on the second encapsulating layer material before the removing of the second photoresist layer; and removing the first protective layer material stacked within the second opening and the second protective layer material stacked within the fifth opening together.

By the embodiments, a defective rate of all pixels may be reduced and a leakage current between the pixels may be prevented by encapsulating each light-emitting element of each pixel of a display device, and moisture permeation from the outside, a lifting defect, and a defect in which an encapsulating layer is not sufficiently filled may be prevented.

### BRIEF DESCRIPTION OF THE DRAWINGS

The above and other exemplary embodiments, advantages and features of this disclosure will become more apparent by describing in further detail exemplary embodiments thereof with reference to the accompanying drawings, in which:

FIG. 1 is a cross-sectional view of an embodiment of pixel electrodes of three pixels of a display device and upper portions of the pixel electrodes,

FIG. 2 is a cross-sectional view of an embodiment of the pixel electrodes of three pixels of the display device and lower portions of the pixel electrodes,

FIG. 3 is a cross-sectional view of an embodiment of three pixels of the display device after a process of a manufacturing method of the display device,

FIG. 4 is a cross-sectional view of three pixels of the display device after a manufacturing process shown in FIG. 3,

FIG. 5 is a view showing a comparison of deposition angles of a common electrode and an intermediate layer during a manufacturing process shown in FIG. 4,

FIG. 6 is a cross-sectional view of three pixels of the display device after the manufacturing process shown in FIG. 4,

FIG. 7 is a cross-sectional view of three pixels of the display device after the manufacturing process shown in FIG. 4,

FIG. 8 is a cross-sectional view of three pixels of the display device after a manufacturing process shown in FIG. 7,

FIG. 9 is a cross-sectional view of three pixels of the display device after a manufacturing process shown in FIG. 8,

FIG. 10 is a cross-sectional view of three pixels of the display device after a manufacturing process shown in FIG. 9,

FIG. 11 is a cross-sectional view of three pixels of the display device after a manufacturing process shown in FIG. 10,

FIG. 12 is a cross-sectional view of three pixels of the display device after a manufacturing process shown in FIG. 11,

FIG. 13 is a cross-sectional view of three pixels of the display device after a manufacturing process shown in FIG. 12,

FIG. 14 is a cross-sectional view of three pixels of the display device after a manufacturing process shown in FIG. 13,

FIG. 15 is a cross-sectional view of another embodiment of pixel electrodes of three pixels of a display device and upper portions of the pixel electrodes, and

FIGS. 16 and 17 are plane views of an embodiment of a display area of the display device.

### DETAILED DESCRIPTION

The disclosure will be described more fully hereinafter with reference to the accompanying drawings, in which embodiments of the disclosure are shown. As those skilled in the art would realize, the described embodiments may be modified in various different ways, all without departing from the spirit or scope of the disclosure.

In order to clarify the disclosure, parts that are not connected with the description will be omitted, and the same elements or equivalents are referred to by the same reference numerals throughout the specification.

Further, since sizes and thicknesses of constituent members shown in the accompanying drawings are arbitrarily given for better understanding and ease of description, the disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are exaggeratedly displayed.

It will be understood that when an element such as a layer, film, region, or substrate is also referred to as being “on” or “above” another element, it may be directly on the other element or intervening elements may also be present. In contrast, when an element is also referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “in a plan view” may mean when an object portion is viewed from above and may mean a view of a plane parallel to a first direction (DR1) and a second direction (DR2), and the phrase “in a cross-section” may mean when a cross-section taken by vertically cutting an object portion is viewed from the side and may mean a view of a cross-section of the object portion cut in a third direction (DR3) perpendicular to the first and second directions (DR1 and DR2).

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

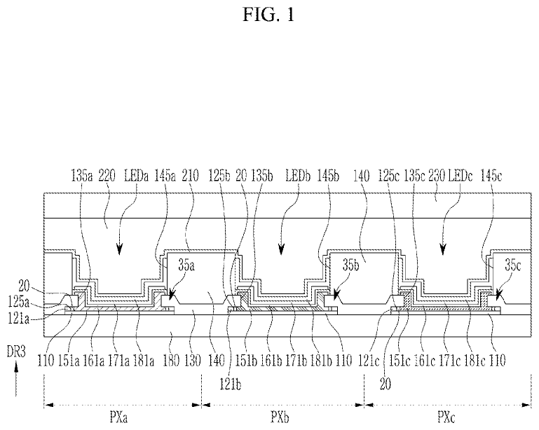

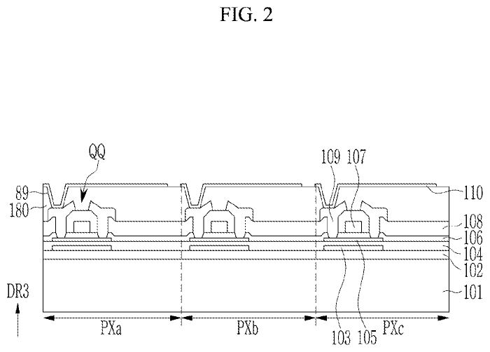

A display device in an embodiment will be described with reference to FIGS. 1 and 2.

FIG. 1 is a cross-sectional view of an embodiment of pixel electrodes of three pixels of a display device and upper portions of the pixel electrodes, and FIG. 2 is a cross-sectional view of an embodiment of the pixel electrodes of three pixels of the display device and lower portions of the pixel electrodes.

The display device in the embodiment includes a display area in which a plurality of pixels capable of displaying an image are disposed.

The plurality of pixels may include a first pixel PXa, a second pixel PXb, a third pixel PXc, or the like capable of emitting light of different colors. FIG. 1 shows three types of pixels capable of emitting light of different colors, but the disclosure is not limited thereto, and the disclosure may include a plurality of pixels capable of emitting light of four different colors. In an embodiment, the first pixel PXa may emit red light, the second pixel PXb may emit green light, and the third pixel PXc may emit blue light, for example. Another embodiment may further include a fourth pixel capable of emitting white light.

Each pixel may include a pixel circuit portion including at least one thin film transistor QQ and a light-emitting element connected to the pixel circuit portion and capable of emitting light. The light-emitting element of each of the pixels PXa, PXb, and PXc may be disposed to correspond to a light-emitting area that is an area capable of emitting light in a plan view.

Referring to FIG. 2, the display device includes a substrate 101. The substrate 101 may include glass or plastic such as polyethylen terephthalate (“PET”), polyethylen naphthalate (“PEN”), polyimide, or the like.

The pixel circuit portion including at least one thin film transistor QQ is disposed above or on the substrate 101. Specifically, a barrier layer 102 that is an insulating layer may be disposed on the substrate 101, and a first conductive layer including a lower pattern 103 may be disposed on the barrier layer 102.

A buffer layer 104 that is an insulating layer may be disposed on the first conductive layer, and an active layer 105 may be disposed on the buffer layer 104. The active layer 105 disposed at each of the pixels PXa, PXb, and PXc may include a channel region forming a channel of the thin film transistor QQ and a conductive region connected to the channel region. The conductive region of the active layer 105 may include a source region and a drain region of the thin film transistor QQ.

The active layer 105 may include a semiconductor material such as amorphous silicon, polycrystalline silicon, an oxide semiconductor, or the like.

A first insulating layer 106 may be disposed on the active layer 105, and a second conductive layer including a gate electrode 107 may be disposed on the first insulating layer 106. The gate electrode 107 may overlap the channel region of the active layer.

A second insulating layer 108 may be disposed on the second conductive layer, and a third conductive layer including a plurality of connection electrodes 109 may be disposed on the second insulating layer 108. The connection electrode 109 may be electrically connected to the conductive region of the active layer 105 through a contact hole of the second insulating layer 108 and a contact hole of the first insulating layer 106.

At least one of the first conductive layer, the second conductive layer, and the third conductive layer may include at least one of metals such as copper (Cu), aluminum (Al), magnesium (Mg), silver (Ag), gold (Au), platinum (Pt), palladium (Pd), nickel (Ni), neodymium (Nd), iridium (Ir), molybdenum (Mo), tungsten (W), titanium (Ti), chromium (Cr), tantalum (Ta), and any alloys thereof. Each of the first conductive layer, the second conductive layer, and the third conductive layer may include a single layer or multiple layers. In an embodiment, the third conductive layer may have a multilayer structure including a lower layer including titanium and an upper layer including copper, for example.

A third insulating layer 180 may be disposed on the third conductive layer.

At least one of the barrier layer 102, the buffer layer 104, the first insulating layer 106, the second insulating layer 108, and the third insulating layer 180 may include an inorganic insulating material such as a silicon nitride (SiNx), a silicon oxide (SiOx), a silicon oxynitride (SiON), or the like and/or an organic insulating material such as polyimide, an acryl-based polymer, a siloxane-based polymer, or the like.

A fourth conductive layer including a plurality of pixel electrodes 110 may be disposed on the third insulating layer 180. Each pixel electrode 110 may be electrically connected to the connection electrode 109 through a contact hole 89 of the third insulating layer 180 to receive a data voltage or current through the thin film transistor QQ. The pixel electrode 110 disposed in each of the pixels PXa, PXb, and PXc may have an island shape, and the pixel electrodes 110 of adjacent pixels PXa, PXb, and PXc may be spaced apart from each other.

The fourth conductive layer may include a semi-transmitting conductive material, a reflective conductive material, or a light-transmitting conductive material.

Referring to FIG. 1, upper patterns 121a, 121b, and 121c are respectively disposed on the pixel electrodes 110 of the pixels PXa, PXb, and PXc. The upper patterns 121a, 121b, and 121c may be disposed on edges of the pixel electrodes 110 corresponding to the upper patterns 121a, 121b, and 121c, and may be formed along the edges of the pixel electrodes 110. Openings 125a, 125b, and 125c may be defined respectively in the upper patterns 121a, 121b, and 121c on the pixel electrodes 110 at middle portions of the pixel electrodes 110.

The upper patterns 121a, 121b, and 121c may include a conductive material or an insulating material, and an embodiment of the conductive material may include a transparent conductive oxide such as indium gallium zinc oxide (“IGZO”) or the like.

The upper patterns 121a, 121b, and 121c may contact upper surfaces of the pixel electrodes 110 corresponding to the upper patterns 121a, 121b, and 121c.

A fourth insulating layer 130 is disposed on the pixel electrodes 110 of the pixels PXa, PXb, and PXc, the upper patterns 121a, 121b, and 121c, and the third insulating layer 180.

Openings 135a, 135b, and 135c are defined in the fourth insulating layer 130 on the middle portions of the pixel electrodes 110 of the pixels PXa, PXb, and PXc. Sizes of the openings 135a, 135b, and 135c of the fourth insulating layer 130 may be smaller than sizes of the openings 125a, 125b, and 125c of the upper patterns 121a, 121b, and 121c corresponding to the openings 135a, 135b, and 135c. Accordingly, the fourth insulating layer 130 may include protrusions 35a, 35b, and 35c that protrude beyond edges of the upper patterns 121a, 121b, and 121c at an upper portion of the edge of each pixel electrode 110. The protrusions 35a, 35b, and 35c may not overlap the upper patterns 121a, 121b, and 121c in a plan view, and may face the pixel electrodes 110 not covered by the upper patterns 121a, 121b, and 121c in the third direction DR3. Edges of the protrusions 35a, 35b, and 35c may define the openings 135a, 135b, and 135c of the fourth insulating layer 130.

The protrusions 35a, 35b, and 35c of the fourth insulating layer 130 may form an undercut structure on the edges of the pixel electrodes 110, and the upper patterns 121a, 121b, and 121c may be disposed below the undercut structure of the fourth insulating layer 130. A space 20 adjacent to the upper patterns 121a, 121b, and 121c may be defined below the protrusions 35a, 35b, and 35c of the fourth insulating layer 130. The space 20 may be filled with air. The space 20 may be omitted. In another embodiment, edges of the openings 125a, 125b, and 125c of the upper patterns 121a, 121b, and 121c may be substantially aligned with edges of the openings 135a, 135b, and 135c of the fourth insulating layer 130.

The fourth insulating layer 130 may include an organic insulating material such as a polyacrylic resin, a polyimide resin, or the like and/or an inorganic insulating material. The fourth insulating layer 130 is also referred to as a pixel defining film. In an embodiment, the fourth insulating layer 130 may include an inorganic insulating material.

An auxiliary electrode 140 may be disposed on the fourth insulating layer 130. Openings 145a, 145b, and 145c are defined in the auxiliary electrode 140 above the middle portions of the pixel electrodes 110 disposed in the pixels PXa, PXb, and PXc.

Sizes of the openings 145a, 145b, and 145c of the auxiliary electrode 140 may be larger than sizes of the openings 135a, 135b, and 135c of the fourth insulating layer 130 corresponding to the openings 145a, 145b, and 145c so that at least a portion of the protrusions 35a, 35b, and 35c of the fourth insulating layer 130 is not be covered by the auxiliary electrode 140 and does not overlap the auxiliary electrode 140 in a plan view. The auxiliary electrode 140 is not disposed within the openings 135a, 135b, and 135c of the fourth insulating layer 130.

The auxiliary electrode 140 may serve to transfer a common voltage to each of the pixels PXa, PXb, and PXc. Auxiliary electrodes 140 may be connected to each other at an entirety of the display area of the display device.

The auxiliary electrode 140 may include a metal such as copper (Cu), molybdenum (Mo), titanium (Ti), aluminum (Al), or the like, or a conductive material such as a transparent conductive oxide or the like, and may include a single layer or multiple layers. In an embodiment, the auxiliary electrode 140 may be a multilayer including an upper layer including copper or titanium and a lower layer including aluminum. When the auxiliary electrode 140 includes multiple layers including different materials, edges of the multiple layers may be substantially aligned with each other in a plan view or an interval between the edges may be within about 1 micrometer.

Intermediate layers 151a, 151b, and 151c including light-emitting layers capable of emitting light of the pixels PXa, PXb, and PXc may be disposed on the pixel electrodes 110. The light-emitting layers included in the intermediate layers 151a, 151b, and 151c may be an organic light-emitting layer, and may be formed using a host and a dopant. The intermediate layers 151a, 151b, and 151c may further include at least one of functional layers such as a hole injection layer, a hole transport layer, an electron transport layer, an electron injection layer, or the like in addition to the light-emitting layer.

The intermediate layers 151a, 151b, and 151c include portions disposed within the openings 135a, 135b, and 135c of the fourth insulating layer 130. The intermediate layers 151a, 151b, and 151c may contact upper surfaces of the pixel electrodes 110 corresponding to the intermediate layers 151a, 151b, and 151c.

The intermediate layers 151a, 151b, and 151c may include portions disposed below the protrusions 35a, 35b, and 35c of the fourth insulating layer 130. That is, the intermediate layers 151a, 151b, and 151c may include portions disposed between the protrusions 35a, 35b, and 35c of the fourth insulating layer 130 and the pixel electrodes 110. The intermediate layers 151a, 151b, and 151c disposed below the protrusions 35a, 35b, and 35c of the fourth insulating layer 130 (i.e., an undercut structure of the protrusions 35a, 35b, and 35c of the fourth insulating layer 130) may be adjacent to the upper patterns 121a, 121b, and 121c. The intermediate layers 151a, 151b, and 151c disposed below the protrusions 35a, 35b, and 35c of the fourth insulating layer 130 may be spaced apart from the upper patterns 121a, 121b, and 121c with the space 20 between the intermediate layers 151a, 151b, and 151c and the upper patterns 121a, 121b, and 121c, and at least a portion of the intermediate layers 151a, 151b, and 151c may contact the upper patterns 121a, 121b, and 121c.

The intermediate layers 151a, 151b, and 151c may further include portions disposed on the protrusions 35a, 35b, and 35c of the fourth insulating layer 130 around the openings 135a, 135b, and 135c of the fourth insulating layer 130. End portions of the intermediate layers 151a, 151b, and 151c disposed on the protrusions 35a, 35b, and 35c of the fourth insulating layer 130 may be spaced apart from the auxiliary electrodes 140 adjacent to the intermediate layers 151a, 151b, and 151c. Accordingly, the intermediate layers 151a, 151b, and 151c of the pixels PXa, PXb, and PXc may be insulated from the auxiliary electrodes 140 so that a leakage current between the pixels PXa, PXb, and PXc that may occur when charges flowing from the auxiliary electrodes 140 flow into the pixel electrodes 110 along the functional layers of the intermediate layers 151a, 151b, and 151c is prevented.

The intermediate layers 151a, 151b, and 151c disposed in the pixels PXa, PXb, and PXc may have an island shape, and the intermediate layers 151a, 151b, and 151c of adjacent pixels PXa, PXb, and PXc may be spaced apart from each other.

The intermediate layers 151a, 151b, and 151c disposed at the pixels PXa, PXb, and PXc may be independently or individually formed in a manufacturing process of the display device. Thicknesses of the intermediate layers 151a, 151b, and 151c of the pixels PXa, PXb, and PXc in the third direction DR3 may be the same as or different from each other.

Common electrodes 161a, 161b, and 161c are disposed on the intermediate layers 151a, 151b, and 151c of the pixels PXa, PXb, and PXc. An edge portion (an end portion) of each of the common electrodes 161a, 161b, and 161c may contact a side surface of the auxiliary electrode 140 adjacent to each of the common electrodes 161a, 161b, and 161c to be electrically connected to the auxiliary electrode 140 so that the edge portion of each of the common electrodes 161a, 161b, and 161c receives a common voltage.

The common electrodes 161a, 161b, and 161c may further include portions disposed above the protrusions 35a, 35b, and 35c of the fourth insulating layer 130.

In a plan view, widths of the common electrodes 161a, 161b, and 161c disposed within the openings 145a, 145b, and 145c of the auxiliary electrodes 140 may be greater than those of the intermediate layers 151a, 151b, and 151c corresponding to the common electrodes 161a, 161b, and 161c. In a plan view, a size or an area of each common electrode 161a, 161b, or 161c may be larger than that of the intermediate layer 151a, 151b, or 151c corresponding to each common electrode 161a, 161b, or 161c.

Each of the common electrodes 161a, 161b, and 161c may include a light-transmitting conductive material or a reflective conductive material.

The common electrodes 161a, 161b, and 161c disposed at the pixels PXa, PXb, and PXc may have an island shape, and the common electrodes 161a, 161b, and 161c of adjacent pixels PXa, PXb, and PXc may be spaced apart from each other.

The pixel electrode 110, each of the intermediate layers 151a, 151b, and 151c, and each of the common electrodes 161a, 161b, and 161c that are disposed at each of the pixels PXa, PXb, and PXc together constitute each of light-emitting diodes LEDa, LEDb, and LEDc that are light-emitting elements, one of the pixel electrode 110 and each of the common electrodes 161a, 161b, and 161c becomes a cathode, and the other one of the pixel electrode 110 and each of the common electrodes 161a, 161b, and 161c becomes an anode. In the illustrated embodiment, a feature in which the pixel electrode 110 becomes the anode and each of the common electrodes 161a, 161b, and 161c becomes the cathode will be described.

Capping layers 171a, 171b, and 171c may be disposed on the common electrodes 161a, 161b, and 161c of the pixels PXa, PXb, and PXc. The capping layers 171a, 171b, and 171c may serve to protect the common electrodes 161a, 161b, and 161c during a manufacturing process of the display device. In an embodiment, the capping layers 171a, 171b, and 171c may include a material such as a hole transport layer, for example, but the disclosure is not limited thereto.

End portions of the capping layers 171a, 171b, and 171c may be spaced apart from the auxiliary electrodes 140 adjacent to the capping layers 171a, 171b, and 171c.

The capping layers 171a, 171b, and 171c disposed at the pixels PXa, PXb, and PXc may have an island shape, and the capping layers 171a, 171b, and 171c of adjacent pixels PXa, PXb, and PXc may be spaced apart from each other.

First encapsulating layers 181a, 181b, and 181c may be disposed on the capping layers 171a, 171b, and 171c of the pixels PXa, PXb, and PXc. The first encapsulating layers 181a, 181b, and 181c may seal the light-emitting elements of the pixels PXa, PXb, and PXc to prevent external oxygen and moisture or the like from penetrating into the light-emitting elements.

The first encapsulating layers 181a, 181b, and 181c of the pixels PXa, PXb, and PXc may cover all regions disposed between the auxiliary electrodes 140 adjacent to the first encapsulating layers 181a, 181b, and 181c to seal the light-emitting elements disposed below the first encapsulating layers 181a, 181b, and 181c from the outside.

A height of a portion of each of the first encapsulating layers 181a, 181b, and 181c overlapping each of the openings 135a, 135b, and 135c of the fourth insulating layer 130 in the third direction DR3 is lower than a height of an upper surface of the auxiliary electrode 140.

Each of the first encapsulating layers 181a, 181b, and 181c of each of the pixels PXa, PXb, and PXc may include a portion disposed at a side surface of the auxiliary electrode 140. An end portion of each of the first encapsulating layers 181a, 181b, and 181c disposed at a side surface of the auxiliary electrode 140 may be disposed lower than the upper surface of the auxiliary electrode 140. That is, the end portion of each of the first encapsulating layers 181a, 181b, and 181c disposed at the side surface of the auxiliary electrode 140 may be spaced apart from the upper surface of the auxiliary electrode 140 in the third direction DR3, and may not be disposed on the upper surface of the auxiliary electrode 140.

The first encapsulating layers 181a, 181b, and 181c disposed at the pixels PXa, PXb, and PXc may have an island shape, and the first encapsulating layers 181a, 181b, and 181c of adjacent pixels PXa, PXb, and PXc may be spaced apart from each other.

A second encapsulating layer 210 may be disposed on each of the first encapsulating layers 181a, 181b, and 181c and the auxiliary electrode 140 of each of the pixels PXa, PXb, and PXc. The second encapsulating layer 210 may be formed as a single layer across the plurality of pixels PXa, PXb, and PXc. The second encapsulating layer 210 may include a portion disposed between adjacent auxiliary electrodes 140 and a region that is connected to the portion disposed between the adjacent auxiliary electrodes 140 and is disposed on the auxiliary electrode 140.

An upper surface of the auxiliary electrode 140 may contact the second encapsulating layer 210. In particular, the second encapsulating layer 210 may cover the first encapsulating layers 181a, 181b, and 181c, and may contact a corner portion of the upper surface of the auxiliary electrode 140.

A third encapsulating layer 220 may be disposed on the second encapsulating layer 210. The third encapsulating layer 220 may be formed as a single layer across the plurality of pixels PXa, PXb, and PXc.

The third encapsulating layer 220 may include an organic material such as an acrylic resin layer, a methacrylic resin layer, polyisoprene, a vinyl resin layer, an epoxy resin layer, a urethane resin layer, a cellulose resin layer, a perylene resin layer, or the like.

A fourth encapsulating layer 230 may be disposed on the third encapsulating layer 220. The fourth encapsulating layer 230 may be formed as a single layer across the plurality of pixels PXa, PXb, and PXc.

The second encapsulating layer 210, the third encapsulating layer 220, and the fourth encapsulating layer 230 may seal the light-emitting elements of the plurality of pixels PXa, PXb, and PXc to prevent external oxygen and moisture or the like from penetrating into the light-emitting elements.

At least one of the first encapsulating layers 181a, 181b, and 181c, the second encapsulating layer 210, and the fourth encapsulating layer 230 may include an inorganic material including at least one of a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide and a silicon oxynitride (SiON).

The first encapsulating layers 181a, 181b, and 181c may seal the pixels PXa, PXb, and PXc, and the second encapsulating layer 210, the third encapsulating layer 220, and the fourth encapsulating layer 230 together may seal the entirety of the display area. The second encapsulating layer 210, the third encapsulating layer 220, and the fourth encapsulating layer 230 are collectively referred to as an encapsulating portion.

In an embodiment, each of the pixels PXa, PXb, and PXc may be sealed so that even when a pixel becomes defective due to a defect factor such as moisture permeation or the like in one pixel, propagation of the defect factor to an adjacent pixel is prevented. Thus, a defective rate of all pixels of the display device may be reduced and a leakage current between the pixels may be prevented.

Referring to FIG. 1, end portions of the first encapsulating layers 181a, 181b, and 181c encapsulating the light-emitting elements of the pixels PXa, PXb, and PXc of the display device in the illustrated embodiment are disposed at side surfaces of the auxiliary electrodes 140 so that the end portions of the first encapsulating layers 181a, 181b, and 181c do not have an undercut structure or an open structure. Accordingly, moisture permeation and a lifting defect around the end portions of the first encapsulating layers 181a, 181b, and 181c may be prevented in a subsequent process after formation of the first encapsulating layers 181a, 181b, and 181c. In addition, the end portions of the first encapsulating layers 181a, 181b, and 181c may not form an undercut structure or a bent portion so that when the third encapsulating layer 220 is stacked, a non-filling that is not filled with an organic material or a void is prevented.

In order to form each of the intermediate layers 151a, 151b, and 151c, each of the common electrodes 161a, 161b, and 161c, and each of the capping layers 171a, 171b, and 171c formed for each of the pixels PXa, PXb, and PXc, there is no protruding shape around an upper corner of the auxiliary electrode 140. Thus, around the upper corner of the auxiliary electrode 140, moisture permeation, a lifting risk, a non-filling in which the third encapsulating layer 220 is not filled with an organic material, or a void do not occur during the manufacturing process.

In an embodiment, a plurality of color conversion layers and a plurality of transmission layers may be disposed above or on the encapsulating portion. The color conversion layer may include a semiconductor nanocrystal including at least one of a phosphor and a quantum dot material that convert light of an incident color to light of a different color. In an embodiment, a plurality of color filters and a plurality of light-blocking layers may be further disposed above or on the plurality of color conversion layers and the plurality of transmission layers.

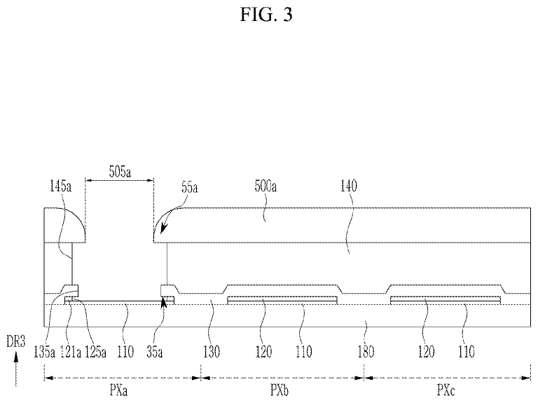

A manufacturing method of the display device in an embodiment will be described with reference to FIGS. 3 to 14 along with FIGS. 1 and 2 described above.

FIG. 3 is a cross-sectional view of an embodiment of three pixels of the display device after a process of the manufacturing method of the display device.

First, referring to FIG. 3 together with FIG. 2 described above, the barrier layer 102, the lower pattern 103, the buffer layer 104, the active layer 105, the first insulating layer 106, the gate electrode 107, the second insulating layer 108, the connection electrode 109, and the third insulating layer 180 are sequentially formed on the substrate 101.

Subsequently, the plurality of pixel electrodes 110 and a plurality of upper layers 120 are formed above or on the third insulating layer 180. The pixel electrode 110 and the upper layer 120 may be patterned through a photolithography process using a single optical mask (or a single photomask), and may be formed to correspond to each of the pixels PXa, PXb, and PXc.

Subsequently, the fourth insulating layer 130 and the auxiliary electrode 140 are sequentially stacked on the upper layer 120 and the third insulating layer 180.

Subsequently, a photoresist layer 500a is stacked on the auxiliary electrode 140, and the stacked photoresist layer 500a is exposed through an optical mask to define an opening 505a that overlaps the pixel electrode 110 of the first pixel PXa and is shown in FIG. 3.

Subsequently, the auxiliary electrode 140 is etched through the opening 505a of the photoresist layer 500a to define an opening 145a at the auxiliary electrode 140, an exposed fourth insulating layer 130 is etched to define an opening 135a at the fourth insulating layer 130, and an exposed upper layer 120 is etched to define the opening 125a at the upper layer 120 disposed at the first pixel PXa so that the upper pattern 121a is formed.

The auxiliary electrode 140 may be etched using wet etching. The auxiliary electrode 140 may be etched further inward than an edge of the opening 505a of the photoresist layer 500a so that an edge of the opening 145a of the auxiliary electrode 140 is disposed outside the edge of the opening 505a of the photoresist layer 500a. That is, a size of the opening 145a of the auxiliary electrode 140 may be larger than a size of the opening 505a of the photoresist layer 500a corresponding to the opening 145a of the auxiliary electrode 140. Accordingly, the photoresist layer 500a may include a protrusion 55a that does not overlap the auxiliary electrode 140 around the opening 505a. An edge of the photoresist layer 500a around the opening 505a of the photoresist layer 500a may form an undercut structure.

The fourth insulating layer 130 may be etched using dry etching. The opening 135a of the fourth insulating layer 130 may be defined substantially aligned with the opening 505a of the photoresist layer 500a due to anisotropy of the dry etching. An edge of the opening 135a of the fourth insulating layer 130 may be disposed inside than an edge of the opening 145a of the auxiliary electrode 140. That is, a size of the opening 135a of the fourth insulating layer 130 may be smaller than a size of the opening 145a of the auxiliary electrode 140 corresponding to the opening 135a of the fourth insulating layer 130.

The upper layer 120 may be etched using wet etching. The upper layer 120 may be etched further than an edge of the opening 135a of the fourth insulating layer 130 due to isotropy of the wet etching so that a protrusion 35a forming an undercut structure is formed at the fourth insulating layer 130. That is, a size of the opening 125a of the upper pattern 121a may be larger than a size of the opening 135a of the fourth insulating layer 130 corresponding to the opening 125a of the upper pattern 121a. However, the disclosure is not limited thereto.

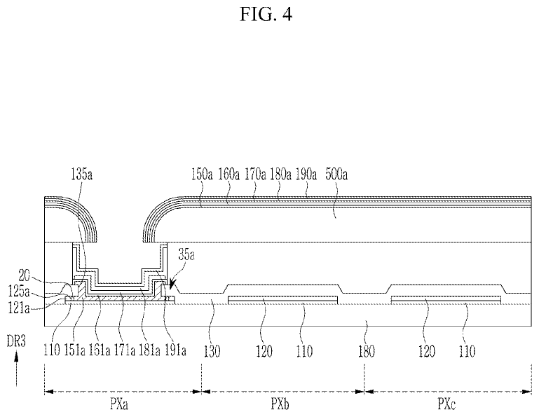

FIG. 4 is a cross-sectional view of three pixels of the display device after the manufacturing process shown in FIG. 3.

Referring to FIG. 4, an intermediate layer material including a light-emitting material, a common electrode material, a capping layer material, a first encapsulating layer material, and a protective layer material are sequentially stacked above or on all pixels PXa, PXb, and PXc. The stacked intermediate layer material forms the intermediate layer 151a disposed within the opening 145a of the auxiliary electrode 140 disposed at the first pixel PXa and an intermediate layer material layer 150a disposed on the photoresist layer 500a. The stacked common electrode material forms the common electrode 161a disposed within the opening 145a of the auxiliary electrode 140 disposed at the first pixel PXa and a common electrode material layer 160a disposed above the photoresist layer 500a. The stacked capping layer material forms the capping layer 171a disposed within the opening 145a of the auxiliary electrode 140 disposed at the first pixel PXa and a capping layer material layer 170a disposed above the photoresist layer 500a. The stacked first encapsulating layer material forms the first encapsulating layer 181a disposed within the opening 145a of the auxiliary electrode 140 disposed at the first pixel PXa and a first encapsulating layer material layer 180a disposed above the photoresist layer 500a. The stacked protective layer material forms a protective layer 191a disposed within the opening 145a of the auxiliary electrode 140 disposed at the first pixel PXa and a protective layer material layer 190a disposed above the photoresist layer 500a.

The protective layer 191a and the protective layer material layer 190a may include a material different from a material of the auxiliary electrode 140. In an embodiment, the protective layer 191a and the protective layer material layer 190a may include a metal oxide such as IGZO or the like, for example.

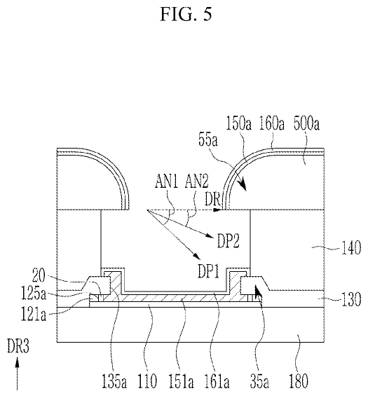

FIG. 5 is a view showing a comparison of deposition angles of the common electrode and the intermediate layer during the manufacturing process shown in FIG. 4.

Referring to FIG. 5 together with FIG. 4, a direction parallel to a plane defined by the first and second directions DR1 and DR2 that is a direction parallel to an upper surface of the substrate 101 or an upper surface of the third insulating layer 180 is also referred to as a plane direction DR. When the intermediate layer material is stacked, an angle defined between a deposition direction DP1 of the intermediate layer material and the plane direction DR is also referred to as a first deposition angle AN1. When the common electrode material is stacked, an angle defined between a deposition direction DP2 of the common electrode material and the plane direction DR is also referred to as a second deposition angle AN2. The second deposition angle AN2 is smaller than the first deposition angle AN1. That is, an acute angle defined between the deposition direction DP2 of the common electrode material and an upper surface of the substrate 101 is smaller than an acute angle defined between the deposition direction DP1 of the intermediate layer material and the upper surface of the substrate 101.

The protrusion 55a forming an undercut structure of the photoresist layer 500a may serve as eaves so that the intermediate layer material incident into the opening 505a of the photoresist layer 500a is deposited to be spaced apart from the auxiliary electrode 140. Thus, an end portion of the intermediate layer 151a may be spaced apart from the auxiliary electrode 140 adjacent to the intermediate layer 151a. In addition, the second deposition angle AN2 may be set to be relatively small so that a region where the common electrode material incident into the opening 505a of the photoresist layer 500a is limited by the protrusion 55a to be deposited contacts a side surface of the auxiliary electrode 140. Thus, an end portion of the common electrode 161a may be electrically connected to the auxiliary electrode 140 by contacting the side surface of the auxiliary electrode 140 adjacent to the common electrode 161a. In a plan view, a width of the common electrode 161a may be greater than that of the intermediate layer 151a.

In an embodiment, the first deposition angle AN1 may be about 40 degrees to about 50 degrees, and a difference between the second deposition angle AN2 and the first deposition angle AN1 may be about 10 degrees or more, for example, but the disclosure is not limited thereto.

In the illustrated embodiment, the common electrode 161a may be deposited to contact the side surface of the auxiliary electrode 140 by a structure in which the protrusion 55a of the photoresist layer 500a protrudes from the side surface of the auxiliary electrode 140.

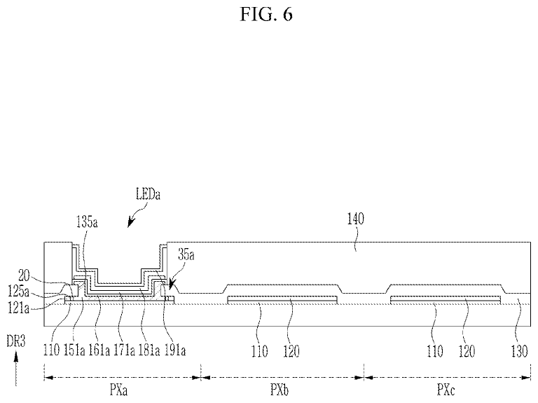

FIG. 6 is a cross-sectional view of three pixels of the display device after the manufacturing process shown in FIG. 4.

Referring to FIG. 6, the photoresist layer 500a is removed so that the intermediate layer material layer 150a, the common electrode material layer 160a, the capping layer material layer 170a, the first encapsulating layer material layer 180a, and the protective layer material layer 190a that are stacked on the photoresist layer 500a are also removed. Accordingly, the light-emitting diode LEDa disposed in the first pixel PXa may be completed.

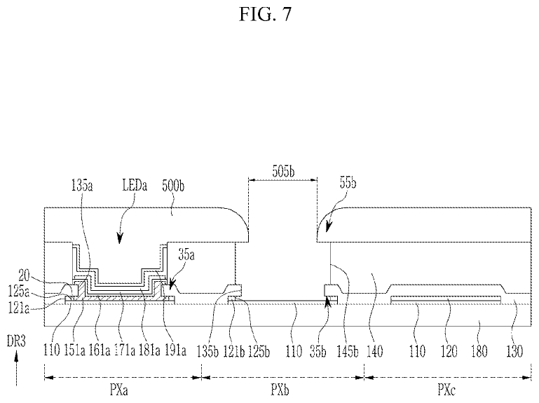

FIG. 7 is a cross-sectional view of three pixels of the display device after the manufacturing process shown in FIG. 4.

Referring to FIG. 7, a photoresist layer 500b is stacked on the auxiliary electrode 140, and the stacked photoresist layer 500b is exposed through an optical mask to define an opening 505b that overlaps the pixel electrode 110 of the second pixel PXb and is shown in FIG. 7.

Subsequently, the auxiliary electrode 140 is etched through the opening 505b of the photoresist layer 500b to define an opening 145b at the auxiliary electrode 140, an exposed fourth insulating layer 130 is etched to define an opening 135b at the fourth insulating layer 130, and an exposed upper layer 120 is etched so that the upper pattern 121b defining the opening 125b is formed.

The auxiliary electrode 140 may be etched using wet etching. The auxiliary electrode 140 may be etched further inward than an edge of the opening 505b of the photoresist layer 500b so that an edge of the opening 145b of the auxiliary electrode 140 is disposed outside the edge of the opening 505b of the photoresist layer 500b. That is, a size of the opening 145b of the auxiliary electrode 140 may be larger than a size of the opening 505b of the photoresist layer 500b corresponding to the opening 145b of the auxiliary electrode 140. Accordingly, the photoresist layer 500b may include a protrusion 55b that does not overlap the auxiliary electrode 140 around the opening 505b. An edge of the photoresist layer 500b around the opening 505b of the photoresist layer 500b may form an undercut structure.

The fourth insulating layer 130 may be etched using dry etching. The opening 135b of the fourth insulating layer 130 may be defined substantially aligned with the opening 505b of the photoresist layer 500b due to anisotropy of the dry etching. An edge of the opening 135b of the fourth insulating layer 130 may be disposed inside than an edge of the opening 145b of the auxiliary electrode 140. That is, a size of the opening 135b of the fourth insulating layer 130 may be smaller than a size of the opening 145b of the auxiliary electrode 140 corresponding to the opening 135b of the fourth insulating layer 130.

The upper layer 120 may be etched using wet etching. The upper layer 120 may be etched further than an edge of the opening 135b of the fourth insulating layer 130 due to isotropy of the wet etching so that a protrusion 35b forming an undercut structure is formed at the fourth insulating layer 130. That is, a size of the opening 125b of the upper pattern 121b may be larger than a size of the opening 135b of the fourth insulating layer 130 corresponding to the opening 125b of the upper pattern 121b. However, the disclosure is not limited thereto.

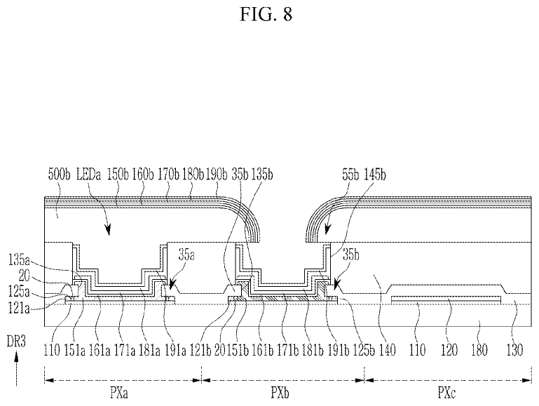

FIG. 8 is a cross-sectional view of three pixels of the display device after the manufacturing process shown in FIG. 7.

Referring to FIG. 8, an intermediate layer material, a common electrode material, a capping layer material, a first encapsulating layer material, and a protective layer material are sequentially stacked above or on all pixels PXa, PXb, and PXc. The stacked intermediate layer material forms the intermediate layer 151b disposed within the opening 145b of the auxiliary electrode 140 disposed at the second pixel PXb and an intermediate layer material layer 150b disposed on the photoresist layer 500b. The stacked common electrode material forms the common electrode 161b disposed within the opening 145b of the auxiliary electrode 140 disposed at the second pixel PXb and a common electrode material layer 160b disposed above the photoresist layer 500b. The stacked capping layer material forms the capping layer 171b disposed within the opening 145b of the auxiliary electrode 140 disposed at the second pixel PXb and a capping layer material layer 170b disposed above the photoresist layer 500b. The stacked first encapsulating layer material forms the first encapsulating layer 181b disposed within the opening 145b of the auxiliary electrode 140 disposed at the second pixel PXb and a first encapsulating layer material layer 180b disposed above the photoresist layer 500b. The stacked protective layer material forms a protective layer 191b disposed within the opening 145b of the auxiliary electrode 140 disposed at the second pixel PXb and a protective layer material layer 190b disposed above the photoresist layer 500b.

The protective layer 191b and the protective layer material layer 190b may include a material different from a material of the auxiliary electrode 140. In an embodiment, the protective layer 191b and the protective layer material layer 190b may include a metal oxide such as IGZO or the like, for example.

When the common electrode material is stacked in the process of FIG. 8, a second deposition angle between a deposition direction of the common electrode material and the plane direction DR shown in FIG. 5 is less than a first deposition angle defined between a deposition direction of the intermediate layer material and the plane direction DR. The protrusion 55b forming an undercut structure of the photoresist layer 500b may serve as eaves so that the incident intermediate layer material is deposited to be spaced apart from the auxiliary electrode 140. Thus, an end portion of the intermediate layer 151b may be spaced apart from the auxiliary electrode 140 adjacent to the intermediate layer 151b. In addition, the second deposition angle may be set to be relatively small so that the deposited region avoiding the protrusion 55b of the photoresist layer 500b is widened. Thus, an edge portion of the common electrode 161b may be electrically connected to the auxiliary electrode 140 by contacting a side surface of the auxiliary electrode 140 adjacent to the common electrode 161b. In a plan view, a width of the common electrode 161b may be greater than that of the intermediate layer 151b.

In the illustrated embodiment, the common electrode 161b may be deposited to contact the side surface of the auxiliary electrode 140 by a structure in which the protrusion 55b of the photoresist layer 500b protrudes from the side surface of the auxiliary electrode 140.

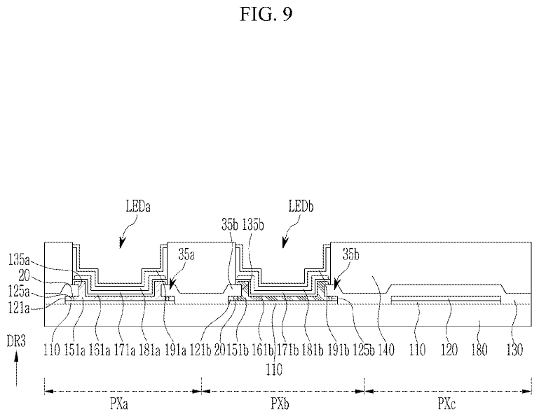

FIG. 9 is a cross-sectional view of three pixels of the display device after the manufacturing process shown in FIG. 8.

Referring to FIG. 9, the photoresist layer 500b (refer to FIG. 8) is removed so that the intermediate layer material layer 150b, the common electrode material layer 160b, the capping layer material layer 170b, the first encapsulating layer material layer 180b, and the protective layer material layer 190b stacked on the photoresist layer 500b are also removed. Accordingly, the light-emitting diode LEDb disposed in the second pixel PXb may be completed.

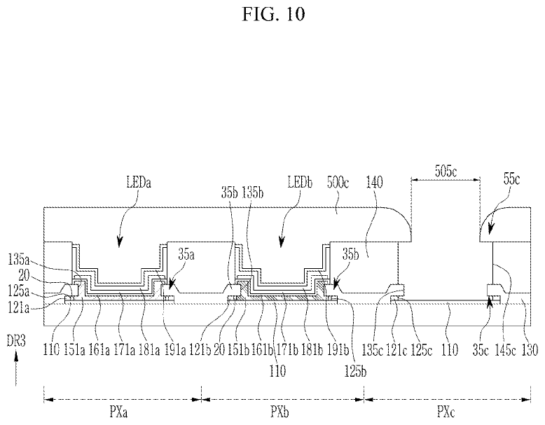

FIG. 10 is a cross-sectional view of three pixels of the display device after the manufacturing process shown in FIG. 9.

Referring to FIG. 10, a photoresist layer 500c is stacked on the auxiliary electrode 140, and the stacked photoresist layer 500c is exposed through an optical mask to define an opening 505c that overlaps the pixel electrode 110 of the third pixel PXc.

Subsequently, the auxiliary electrode 140 is etched through the opening 505c of the photoresist layer 500c to define an opening 145c at the auxiliary electrode 140, an exposed fourth insulating layer 130 is etched to define an opening 135c at the fourth insulating layer 130, and an exposed upper layer 120 is etched so that the upper pattern 121c defining the opening 125c is formed.

The auxiliary electrode 140 may be etched using wet etching. The auxiliary electrode 140 may be etched further inward than an edge of the opening 505c of the photoresist layer 500c so that an edge of the opening 145c of the auxiliary electrode 140 is disposed outside the edge of the opening 505c of the photoresist layer 500c. That is, a size of the opening 145c of the auxiliary electrode 140 may be larger than a size of the opening 505c of the photoresist layer 500c corresponding to the opening 145c of the auxiliary electrode 140. Accordingly, the photoresist layer 500c may include a protrusion 55c that does not overlap the auxiliary electrode 140 around the opening 505c. An edge of the photoresist layer 500c around the opening 505c of the photoresist layer 500c may form an undercut structure.

The fourth insulating layer 130 may be etched using dry etching. The opening 135c of the fourth insulating layer 130 may be defined substantially aligned with the opening 505c of the photoresist layer 500c due to anisotropy of the dry etching. An edge of the opening 135c of the fourth insulating layer 130 may be disposed inside than an edge of the opening 145c of the auxiliary electrode 140. That is, a size of the opening 135c of the fourth insulating layer 130 may be smaller than a size of the opening 145c of the auxiliary electrode 140 corresponding to the opening 135c of the fourth insulating layer 130.

The upper layer 120 may be etched using wet etching. The upper layer 120 may be etched further than an edge of the opening 135c of the fourth insulating layer 130 due to isotropy of the wet etching so that a protrusion 35c forming an undercut structure is formed at the fourth insulating layer 130. That is, a size of the opening 125c of the upper pattern 121c may be larger than a size of the opening 135c of the fourth insulating layer 130 corresponding to the opening 125c of the upper pattern 121c. However, the disclosure is not limited thereto.

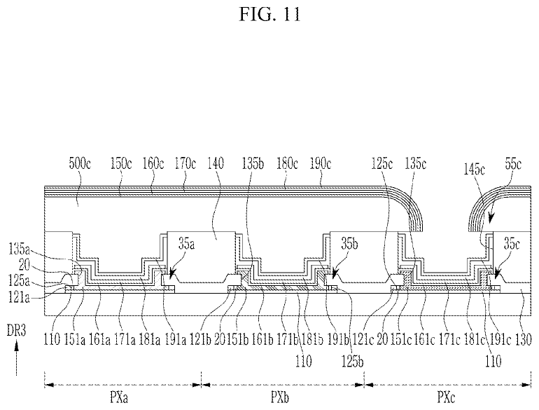

FIG. 11 is a cross-sectional view of three pixels of the display device after the manufacturing process shown in FIG. 10.

Referring to FIG. 11, an intermediate layer material, a common electrode material, a capping layer material, a first encapsulating layer material, and a protective layer material are sequentially stacked above or on all pixels PXa, PXb, and PXc. The stacked intermediate layer material forms the intermediate layer 151c disposed within the opening 145c of the auxiliary electrode 140 disposed at the third pixel PXc and an intermediate layer material layer 150c disposed on the photoresist layer 500c. The stacked common electrode material forms the common electrode 161c disposed within the opening 145c of the auxiliary electrode 140 disposed at the third pixel PXc and a common electrode material layer 160c disposed above the photoresist layer 500c. The stacked capping layer material forms the capping layer 171c disposed within the opening 145c of the auxiliary electrode 140 disposed at the third pixel PXc and a capping layer material layer 170c disposed above the photoresist layer 500c. The stacked first encapsulating layer material forms the first encapsulating layer 181c disposed within the opening 145c of the auxiliary electrode 140 disposed at the third pixel PXc and a first encapsulating layer material layer 180c disposed above the photoresist layer 500c. The stacked protective layer material forms a protective layer 191c disposed within the opening 145c of the auxiliary electrode 140 disposed at the third pixel PXc and a protective layer material layer 190c disposed above the photoresist layer 500c.

The protective layer 191c and the protective layer material layer 190c may include a material different from a material of the auxiliary electrode 140. In an embodiment, the protective layer 191c and the protective layer material layer 190c may include a metal oxide such as IGZO or the like, for example.

When the common electrode material is stacked in the process of FIG. 11, a second deposition angle between a deposition direction of the common electrode material and the plane direction DR shown in FIG. 5 is less than a first deposition angle defined between a deposition direction of the intermediate layer material and the plane direction DR. The protrusion 55c forming an undercut structure of the photoresist layer 500c may serve as eaves so that the incident intermediate layer material is deposited to be spaced apart from the auxiliary electrode 140. Thus, an end portion of the intermediate layer 151c may be spaced apart from the auxiliary electrode 140 adjacent to the intermediate layer 151c. In addition, the second deposition angle may be set to be relatively small so that the deposited region avoiding the protrusion 55c of the photoresist layer 500c is widened. Thus, an edge portion of the common electrode 161c may be electrically connected to the auxiliary electrode 140 by contacting a side surface of the auxiliary electrode 140 adjacent to the common electrode 161c. In a plan view, a width of the common electrode 161c may be greater than that of the intermediate layer 151c.

In the illustrated embodiment, the common electrode 161c may be deposited to contact the side surface of the auxiliary electrode 140 by a structure in which the protrusion 55c of the photoresist layer 500c protrudes from the side surface of the auxiliary electrode 140.

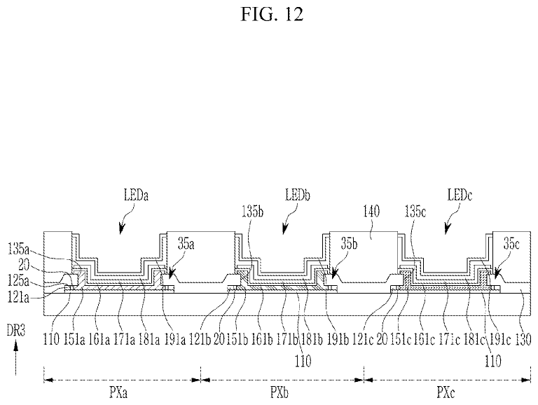

FIG. 12 is a cross-sectional view of three pixels of the display device after the manufacturing process shown in FIG. 11.

Referring to FIG. 12, the photoresist layer 500c is removed so that the intermediate layer material layer 150c, the common electrode material layer 160c, the capping layer material layer 170c, the first encapsulating layer material layer 180c, and the protective layer material layer 190c stacked on the photoresist layer 500c are also removed. Accordingly, the light-emitting diode LEDc disposed at the third pixel PXc may be completed.

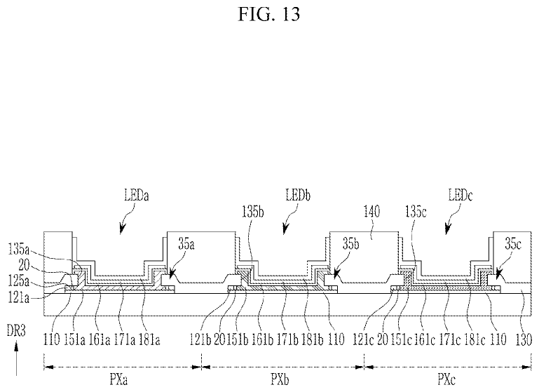

FIG. 13 is a cross-sectional view of three pixels of the display device after the manufacturing process shown in FIG. 12.

Referring to FIG. 13, the protective layers 191a, 191b, and 191c of the pixels PXa, PXb, and PXc that function to protect the first encapsulating layers 181a, 181b, and 181c in the etching process are removed. In this case, an etchant used when the protective layers 191a, 191b, and 191c are removed may be an etchant having a relatively high selectivity ratio of the protective layers 191a, 191b, and 191c with respect to a material of the auxiliary electrode 140 so that the auxiliary electrode 140 is not etched together.

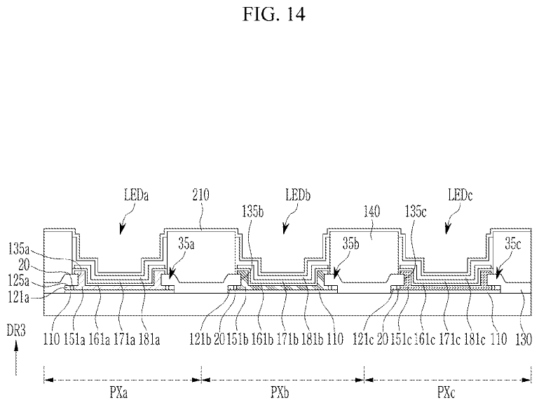

FIG. 14 is a cross-sectional view of three pixels of the display device after the manufacturing process shown in FIG. 13.

Referring to FIG. 14, the second encapsulating layer 210 is formed by depositing an inorganic insulating material above or on all pixels PXa, PXb, and PXc.

Next, referring to FIG. 1, an organic insulating material is stacked above or on all pixels PXa, PXb, and PXc to form the third encapsulating layer 220 disposed on the second encapsulating layer 210, and an inorganic insulating material is stacked on the third encapsulating layer 220 to form the fourth encapsulating layer 230 disposed on the third encapsulating layer 220.

According to the manufacturing method in the illustrated embodiment, the auxiliary electrode 140 itself does not need to form an undercut structure, the intermediate layer material layer, the common electrode material layer, the capping layer material layer, a first encapsulating layer material layer, or the like are disposed at an upper portion of the auxiliary electrode 140, and no protrusion structure or undercut structure by the materials exists at the upper portion of the auxiliary electrode 140. Therefore, around an upper corner of the auxiliary electrode 140, moisture permeation, a lifting risk, a non-filling in which the third encapsulating layer 220 is not filled with an organic material, or a void do not occur during the manufacturing process.

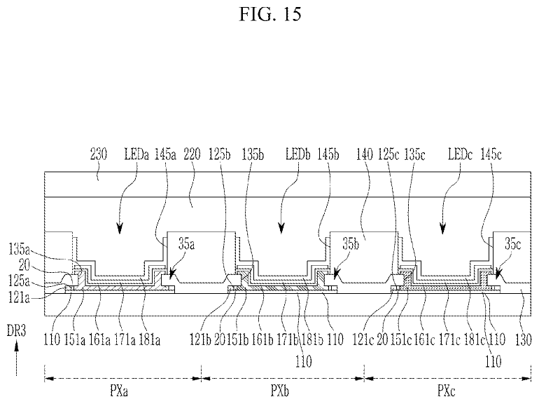

A display device in another embodiment will be described with reference to FIG. 15 together with the previously described drawings.

FIG. 15 is a cross-sectional view of another embodiment of pixel electrodes of three pixels of a display device and upper portions of the pixel electrodes.

Referring to FIG. 15, the display device and a manufacturing method of the display device in the illustrated embodiment are mostly the same as the previously described embodiment, but the second encapsulating layer 210 and the manufacturing process of the second encapsulating layer 210 may be omitted. In particular, when an upper portion of the auxiliary electrode 140 includes a material that does not form an oxide film, the second encapsulating layer 210 may be omitted. In this case, the third encapsulating layer 220 may contact an upper surface of the auxiliary electrode 140. In particular, the third encapsulating layer 220 may cover the first encapsulating layers 181a, 181b, and 181c, and may contact a corner portion of the upper surface of the auxiliary electrode 140.

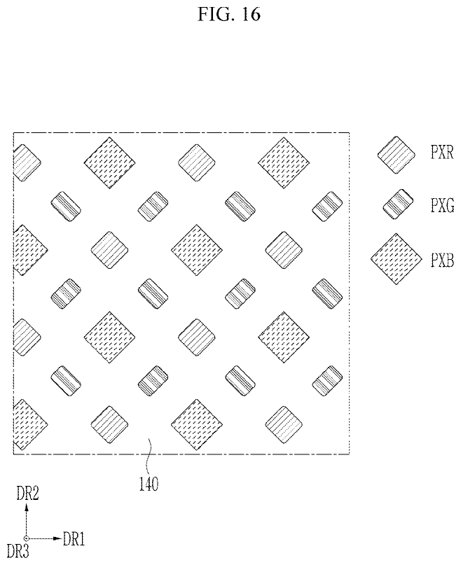

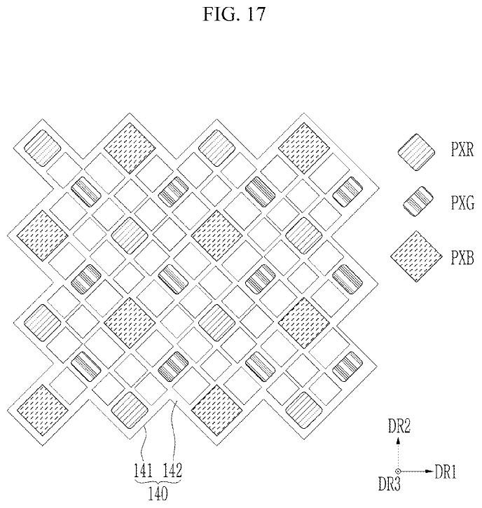

A display device in an embodiment will be described with reference to FIGS. 16 and 17 together with the previously described drawings.

FIGS. 16 and 17 are plane views of a display area of the display device.

Referring to FIGS. 16 and 17, a plurality of pixels is disposed in a plan view defined by the first and second directions DR1 and DR2. The plurality of pixels may include a first color pixel PXR, a second color pixel PXG, and a third color pixel PXB capable of emitting light of different colors. The first pixel PXa, the second pixel PXb, and the third pixel PXc described above may sequentially correspond to the first color pixel PXR, the second color pixel PXG, and the third color pixel PXB. In an embodiment, the first color may be red, the second color may be green, and the third color may be blue, for example, but the disclosure is not limited thereto.

A plurality of first color pixels PXR, a plurality of second color pixels PXG, and a plurality of third color pixels PXB are respectively disposed in a diagonal direction oblique to the first and second directions DR1 and DR2. The first color pixels PXR and the third color pixels PXB may be alternately disposed in the first and second directions DR1 and DR2, the first color pixels PXR and the second color pixels PXG may be alternately disposed in a diagonal direction, and the second color pixels PXG and third color pixels PXB may be alternately disposed in the diagonal direction. The second color pixel PXG may have the smallest size, and the third color pixel PXB may have the largest size, but the disclosure is not limited thereto.

Areas of the first color pixel PXR, the second color pixel PXG, and the third color pixel PXB shown in FIGS. 16 and 17 may be light-emitting areas of each pixel.

Referring to FIG. 16, the auxiliary electrode 140 in an embodiment may be formed in most areas except for light-emitting areas of the plurality of pixels PXR, PXG, and PXB. The auxiliary electrode 140 may have a mesh shape with openings in an area of an entirety of the display area except for the light-emitting areas of the plurality of pixels PXR, PXG, and PXB.

Referring to FIG. 17, the auxiliary electrode 140 in an embodiment may include portions 141 surrounding the light-emitting areas of the plurality of pixels PXR, PXG, and PXB and a connection portion 142 connecting the portions 141. The auxiliary electrode 140 may form a mesh shape in the display area together with the portions 141 and the connection portions 142. That is, a portion except for the portions 141 and the connection portions 142 of the auxiliary electrode 140 may be a region in which the auxiliary electrode 140 is not formed.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A display device comprising:
a substrate;
a plurality of pixel electrodes which are disposed above the substrate;
a first insulating layer in which a first opening is defined and which is disposed on a pixel electrode of the plurality of pixel electrodes;
an auxiliary electrode which is disposed on the first insulating layer;
an intermediate layer which is disposed on the pixel electrode and includes a light-emitting layer disposed within the first opening;
a common electrode which is disposed on the intermediate layer; and
a first encapsulating layer which is disposed above the common electrode,
wherein an end portion of the common electrode contacts a side surface of the auxiliary electrode and is electrically connected to the side surface of the auxiliary electrode, and an end portion of the first encapsulating layer is disposed at the side surface of the auxiliary electrode and is disposed lower than an upper surface of the auxiliary electrode.

2. The display device of claim 1, further comprising a second encapsulating layer disposed on the first encapsulating layer and the auxiliary electrode,
wherein the second encapsulating layer contacts the upper surface of the auxiliary electrode.

3. The display device of claim 2, wherein the second encapsulating layer contacts a corner portion of the upper surface of the auxiliary electrode.

4. The display device of claim 2, further comprising a third encapsulating layer disposed on the second encapsulating layer,
wherein at least one of the first encapsulating layer and the second encapsulating layer comprises an inorganic material, and the third encapsulating layer comprises an organic material.

5. The display device of claim 2, wherein the first encapsulating layer comprises an inorganic material, and the second encapsulating layer comprises an organic material.

6. The display device of claim 1, wherein a second opening corresponding to the first opening is defined in the auxiliary electrode, and a width of the common electrode disposed within the second opening is greater than a width of the intermediate layer disposed within the second opening.

7. The display device of claim 6, wherein the first insulating layer includes a protrusion defining the first opening and having an undercut structure, and the display device further includes an upper pattern disposed between the protrusion and the pixel electrode.

8. The display device of claim 7, wherein the intermediate layer comprises a portion disposed below the protrusion and spaced apart from the upper pattern.

9. The display device of claim 1, further comprising a capping layer disposed between the common electrode and the first encapsulating layer.

10. The display device of claim 1, wherein the auxiliary electrode forms a mesh shape at a display area where the plurality of pixel electrodes is disposed.

11. A display device comprising:
a substrate;
a plurality of pixel electrodes which are disposed above the substrate;
a first insulating layer in which a first opening is defined and which is disposed on a pixel electrode of the plurality of pixel electrodes;
an auxiliary electrode which is disposed on the first insulating layer;
an intermediate layer which is disposed on the pixel electrode and includes a light-emitting layer disposed within the first opening;
a common electrode which is disposed on the intermediate layer;
a first encapsulating layer which is disposed above the common electrode; and
a second encapsulating layer disposed on the first encapsulating layer and the auxiliary electrode,
wherein an end portion of the common electrode contacts a side surface of the auxiliary electrode and is electrically connected to the side surface of the auxiliary electrode, and the second encapsulating layer covers the first encapsulating layer and contacts a corner portion of an upper surface of the auxiliary electrode.

12. The display device of claim 11, wherein the second encapsulating layer includes a portion disposed on the upper surface of the auxiliary electrode and a portion disposed on the first encapsulating layer.

13. The display device of claim 12, further comprising a third encapsulating layer disposed on the second encapsulating layer,
wherein at least one of the first encapsulating layer and the second encapsulating layer comprises an inorganic material, and the third encapsulating layer comprises an organic material.

14. The display device of claim 12, wherein the first encapsulating layer comprises an inorganic material, and the second encapsulating layer comprises an organic material.

15. The display device of claim 11, wherein a second opening corresponding to the first opening is defined in the auxiliary electrode, and a width of the common electrode disposed within the second opening is greater than a width of the intermediate layer disposed within the second opening.

16. The display device of claim 15, wherein the first insulating layer includes a protrusion defining the first opening and having an undercut structure, and the display device further includes an upper pattern disposed between the protrusion and the pixel electrode.

17. A manufacturing method of a display device, comprising:
forming a plurality of pixel electrodes above a substrate;
sequentially forming a first insulating layer and an auxiliary electrode on the plurality of pixel electrodes;
stacking a first photoresist layer on the auxiliary electrode and defining a first opening overlapping a first pixel electrode of the plurality of pixel electrodes;
etching the auxiliary electrode through the first opening and defining a second opening corresponding to the first opening and etching the first insulating layer and defining a third opening corresponding to the second opening;
sequentially stacking a first intermediate layer material including a light-emitting material, a first common electrode material, and a first encapsulating layer material above the substrate; and
removing the first photoresist layer and forming a first intermediate layer, a first common electrode, and a first encapsulating layer sequentially disposed on the first pixel electrode,
wherein an acute angle defined between a deposition direction of the first common electrode material and an upper surface of the substrate is smaller than an acute angle defined between a deposition direction of the first intermediate layer material and the upper surface of the substrate.

18. The manufacturing method of the display device of claim 17, wherein the first photoresist layer includes a protrusion which does not overlap the auxiliary electrode around the first opening, and by the protrusion, the first intermediate layer material incident into the first opening is spaced apart from the auxiliary electrode, and the first common electrode material contacts the auxiliary electrode.

19. The manufacturing method of the display device of claim 18, further comprising:
stacking a second photoresist layer on the auxiliary electrode and defining a fourth opening overlapping a second pixel electrode of the plurality of pixel electrodes;
etching the auxiliary electrode through the fourth opening and defining a fifth opening corresponding to the fourth opening and etching the first insulating layer and defining a sixth opening corresponding to the fifth opening;
sequentially stacking a second intermediate layer material including a light-emitting material, a second common electrode material, and a second encapsulating layer material above the substrate; and
removing the second photoresist layer and forming a second intermediate layer, a second common electrode, and a second encapsulating layer sequentially disposed on the second pixel electrode,
wherein an acute angle defined between a deposition direction of the second common electrode material and the upper surface of the substrate is smaller than an acute angle defined between a deposition direction of the second intermediate layer material and the upper surface of the substrate.

20. The manufacturing method of the display device of claim 19, further comprising:
stacking a first protective layer material on the first encapsulating layer material before the removing of the first photoresist layer;
stacking a second protective layer material on the second encapsulating layer material before the removing of the second photoresist layer; and
removing the first protective layer material stacked within the second opening and the second protective layer material stacked within the fifth opening together.
